(19) United States
(12) Patent Application Publication
(10) Pub. No.: US 2019/0112698 A1
(43) Pub. Date: Apr. 18, 2019

(54) TRIM COMPONENT HAVING TEXTURED SURFACE SUPPORTING PVD-DEPOSITED COATING, AND/OR METHOD OF MAKING THE SAME

(71) Applicant: SRG Global, Inc., Troy, MI (US)

(72) Inventors: Xuequn HU, Northville, MI (US); Jerry Lawrence LOGSDON, Temperance, MI (US)

(21) Appl. No.: 15/782,394

(22) Filed: Oct. 12, 2017

(51) Int. Cl. C23C 14/00; C23C 14/34; B60R 13/04; B60R 13/02

(52) U.S. Cl. CPC C23C 14/0015; C23C 14/3442; C23C 16/006; B60R 13/02; B60R 13/04

(57) ABSTRACT

Certain example embodiments of this invention relate to trim components having textured surfaces that support physical vapor deposition (PVD) deposited thin film coatings, and/or methods of making the same. A plastic substrate has a surface to be coated that is textured so that PVD-deposited layers formed thereon are generally conformal thereto and provide a desired matte or glossy aesthetic for the trim component. An adhesion promoting base layer and an overcoat sandwich a metal-inclusive layer, and each of these layers may be PVD-deposited on the textured plastic substrate surface. The adhesion promoting base layer and the overcoat are optional. Layers of metal, transition element, and/or other materials may be used to provide the desired coloration in certain example embodiments. The trim components may be used for interior and/or exterior vehicle or other applications, e.g., in connection with functional and/or decorative elements.

### TECHNICAL FIELD

Certain example embodiments of this invention relate to trim components for automobiles, trucks, and/or other vehicles, and/or methods of making the same. More particularly, certain example embodiments of this invention relate to trim components having textured surfaces that support physical vapor deposition (PVD) deposited thin film coatings, and/or methods of making the same.

### BACKGROUND AND SUMMARY

Trim components for automobiles, trucks, and/or other vehicles are known in the art. Trim components can be found inside and/or outside of vehicles. Chrome trim components are oftentimes seen as having a pleasing aesthetic. However, for cost and other considerations, chrome trim components have been replaced with alternative materials that oftentimes involve chrome coatings and/or otherwise look like chrome.

Plastics, for example, have been successfully used in trim component applications. Such plastic products typically are designed to meet durability, scratch, corrosion, and chemical resistance requirements, while also having a desirable aesthetic appearance. Because plastics typically are soft and generally cannot themselves provide a metal-like aesthetic, metallic and/or ceramic coatings oftentimes are formed thereon.

Electroplating, for example, is one common way to form a chrome-looking plastic trim component. Electroplating for such applications typically involves the formation of a copper-nickel-chromium layer that is about 30 microns thick. Electroplating oftentimes levels imperfections in the plastic substrate, resulting in a smooth coating with a desirable appearance. Unfortunately, however, electroplating involves a difficult to administer wet process. It also presents environmental and safety concerns and therefore is subject to strict regulations, and in some situations even banned, in the U.S., Europe, and elsewhere and, ultimately, is being phased out of production lines.

One alternative to electroplating plastics involves physical vapor deposition (PVD). A PVD coating can be formed through a “dry process” such as sputtering and typically is more environmentally friendly and safer, compared to electroplating. A potentially wide range of coating materials can be used to produce different metallic colors.

PVD layers oftentimes are formed to have a thickness of 0.01-0.5 microns. Such coatings typically are conformal and thus non-leveling with respect to the underlying substrate. A lacquer or other base coat material therefore is oftentimes used with a thickness sufficient to serve this leveling function. Alternatively, high-quality molds can be used to obtain a highly-polished surface.

One issue with current PVD layers on plastic relates to adhesion. Because plastics are polymers, the adhesion of inorganic materials thereto can be difficult. To help address this problem, the surface can be activated to change its activation energy and contact angle. For instance, activation can be performed using a carefully-controlled plasma in a reactive environment (e.g., including nitrogen and/or oxygen gas) or a non-reactive environment (e.g., including argon gas). The surface activation leads to an increase in surface energy to above 110 mJ/m² in some instances. Different activation techniques may be appropriate with different polymers.

One current solution involves a plastic substrate with a UV-cured base layer that is spray-coated thereon for adhesion purposes. A PVD-deposited chrome coating is then applied thereon. A UV-cured top coat with or without particle doping is provided on the PVD-deposited chrome coating in order to simulate either bright chrome or matte chrome. A variation of this approach involves replacing the UV-cured top coat with a plasma-assisted chemical vapor deposition (PACVD) deposited layer comprising silicon oxide, which provides mechanical protection for the underlying PVD-deposited chrome coating.

Although current PVD coatings are advantageous from environmental and safety concerns compared to electroplated samples, they unfortunately do not provide the same desired aesthetic. For example, it is difficult to obtain a “shiny” surface typical with chrome coatings. Moreover, even when trying to obtain a matte finish type aesthetic, the products have a warm-looking surface and appear “plasticy.”

Certain example embodiments address these and/or other concerns. For example, certain example embodiments relate to improved trim components and/or methods of making the same. The trim components of certain example embodiments provide improved aesthetic features, thereby more closely matching the look of chrome or other finishes and serving as an improved alternative electroplating.

In certain example embodiments, a method of making a trim component for a vehicle is provided. The trim component includes a plastic substrate, and the plastic substrate includes a surface to be coated that is formed to have a first desired roughness profile. A color-providing layer is physical vapor deposition deposited, directly or indirectly, on the surface to be coated, with the color-providing layer being formed to have a roughness, coloration, and gloss, sufficient to impart a desired warm or cool aesthetic appearance for the trim component.

In certain example embodiments, a method of making a vehicle may include, for example, having a trim component made in accordance with the example techniques described herein. An electronic component is provided and connected to a controller via an electronic interface. The trim component is oriented in the vehicle in a desired spatial relation relative to the electronic component.

In certain example embodiments, a metallic-looking trim component for a vehicle is provided. A physical vapor deposition (PVD) deposited color-providing layer is formed, directly or indirectly, on the surface, with the color-providing layer being formed to have a roughness, coloration, and gloss, sufficient to impart a desired warm or cool aesthetic appearance for the metallic-looking trim component.

According to certain example embodiments, e.g., where it is desirable to provide a chrome finish, the trim component may have optical properties including an L* value of 80 to 85 (more preferably 80 to 82.5); an a* value of 0 to −1.5 (more preferably −0.79 to −0.85); and a b* value of 0 to −1.5 (more preferably 0 to −0.4), e.g., if a matte appearance is desired. In other example embodiments, a more gloss chrome-looking trim component may be provided.

According to certain example embodiments, an optional base layer may be provide and may comprise, for example, SiOx, where 1<x≤2.

According to certain example embodiments, an overcoat layer may be provided and it may comprise, for example, ZrOx and/or SiNx.

According to certain example embodiments, an optional functional coating may be located over the overcoat layer.

The features, aspects, advantages, and example embodiments described herein may be combined to realize yet further embodiments.

### BRIEF DESCRIPTION OF THE DRAWINGS

The file of this patent contains at least one drawing/photograph executed in color. Copies of this patent with color drawing(s)/photograph(s) will be provided by the Office upon request and payment of the necessary fee.

These and other features and advantages may be better and more completely understood by reference to the following detailed description of exemplary illustrative embodiments in conjunction with the drawings, of which:

FIGS. 1a-1e are laser and optical images of example chrome electroplated sample surfaces that have matte finishes and may be mimicked by the physical vapor deposition (PVD) coated surfaces of certain example embodiments;

FIGS. 2a-2e are images showing the height of the samples shown in FIGS. 1a-1e;

FIGS. 3a-3e are three-dimensional images of the samples shown in FIGS. 1a-1e;

FIG. 4 is a cross-sectional view of a trim component supporting a coating in accordance with certain example embodiments;

FIG. 5 is a schematic view of a trim component with an associated electronic device, in accordance with certain example embodiments; and

FIG. 6 is a flowchart showing a method of making the FIG. 5 example trim component, in accordance with certain example embodiments.

### DETAILED DESCRIPTION

Certain example embodiments of this invention relate to trim components having textured surfaces that support physical vapor deposition (PVD) deposited thin film coatings, and/or methods of making the same. More particularly, certain example embodiments use PVD sputtering technology and molded plastic surfaces to achieve matte and decorative features. For trim components where it is desirable to provide a satin chrome aesthetic, certain example embodiments make use of a molded matte surface to provide for an improved satin appearance and good adhesion between the overlying layer stack and the plastic substrate, together with PVD-deposited chrome (and/or other metal-inclusive materials) and additional PVD-deposited sputtered top layer(s). For trim components where it is desirable to provide a bright chrome aesthetic, certain example embodiments make use of a PVD-deposited base layer for adhesion purposes, PVD-deposited chrome (and/or other metal-inclusive materials), and additional PVD-deposited sputtered top layer(s).

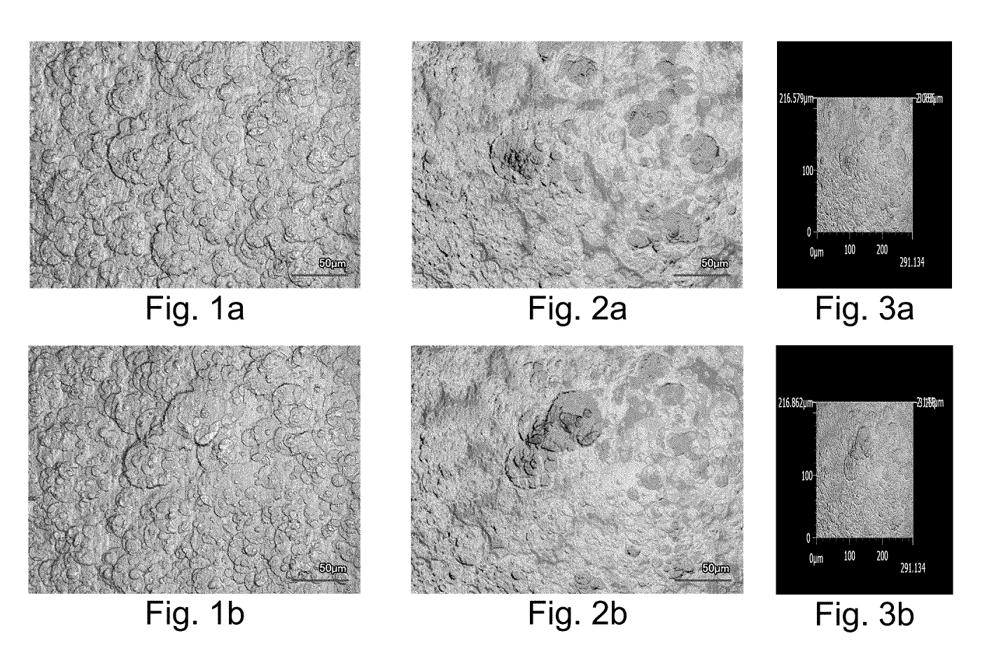

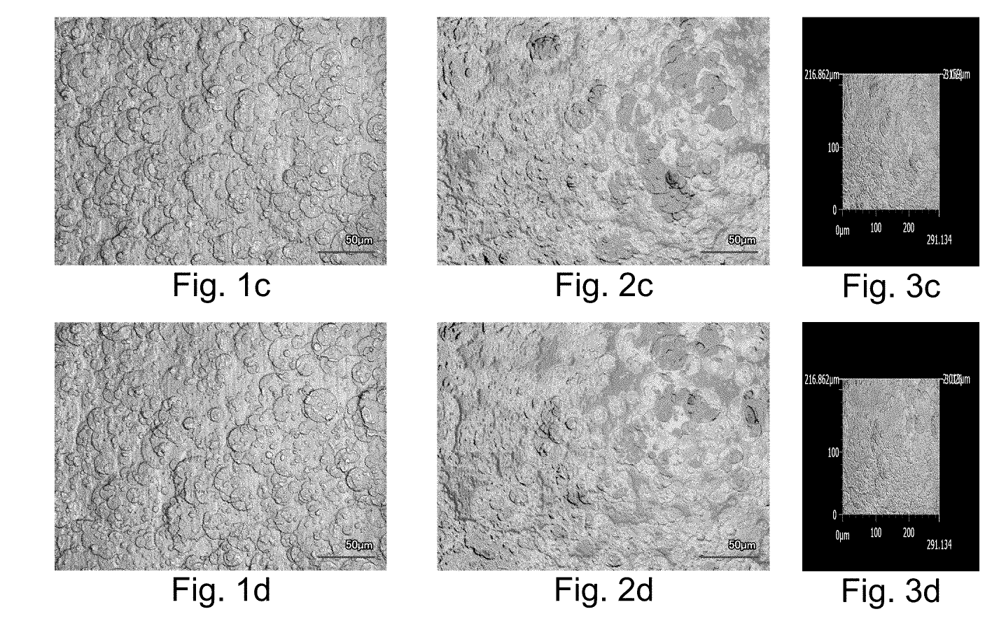

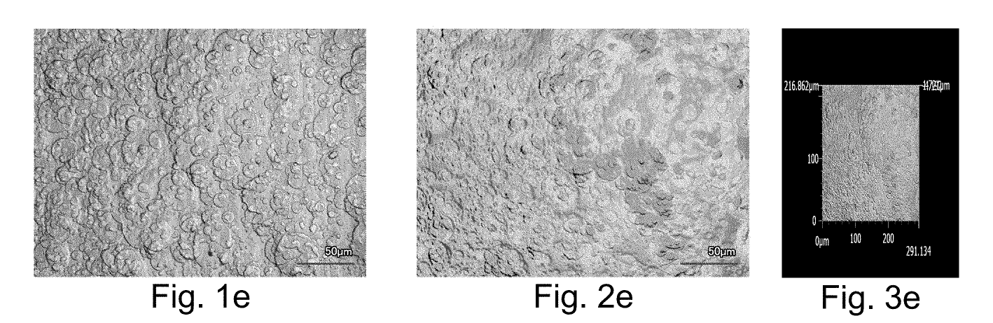

FIGS. 1a-3e are images relating to conventional chrome electroplated samples. That is, FIGS. 1a-1e are laser and optical images of example chrome electroplated sample surfaces that have matte finishes and may be mimicked by the physical vapor deposition (PVD) coated surfaces of certain example embodiments; FIGS. 2a-2e are images showing the height of the samples shown in FIGS. 1a-1e; and FIGS. 3a-3e are three-dimensional images of the samples shown in FIGS. 1a-1e. These samples had desirable aesthetics and therefore were example “targets” for mimicking when developing the approach described herein. The following table includes roughness information for each of the five samples, with the “Chrome 1” label in the table providing data for the FIG. 1a/2a/3a sample, the “Chrome 2” label in the table providing data for the FIG. 1b/2b/3b sample, the “Chrome 3” label in the table providing data for the the FIG. 1c/2c/3c sample, etc. The bottom row in the table represents the averaged values for the five samples.

| | Ra | | Rz | | RSm | |
|---|---|---|---|---|---|---|
| | Avg. | Std. Dev. | Avg. | Std. Dev. | Avg. | Std. Dev. |
| | (um) | (um) | (um) | (um) | (um) | (um) |
| Chrome 1 | 0.366 | 0.040 | 2.876 | 0.364 | 47.174 | 17.421 |
| Chrome 2 | 0.366 | 0.046 | 3.024 | 0.387 | 51.599 | 21.444 |
| Chrome 3 | 0.311 | 0.030 | 2.726 | 0.344 | 39.844 | 10.246 |
| Chrome 4 | 0.320 | 0.037 | 2.913 | 0.432 | 43.914 | 14.339 |
| Chrome 5 | 0.292 | 0.038 | 2.726 | 0.390 | 40.710 | 12.958 |
| | 0.331 | 0.038 | 2.853 | 0.383 | 44.648 | 15.281 |

In the table provided above, the Ra values represent the arithmetic mean heights of the features, the Rz values represent the maximum feature heights, and the Rsm values represent the mean widths of the profile elements. As noted above, this data corresponds to desirable-looking matte finished products. It has been found that molded components that have yet smoother surfaces tend to yield “shinier” or brighter surfaces more easily. Desirable-appearing matte finishes, however, have been found to be more difficult to produce.

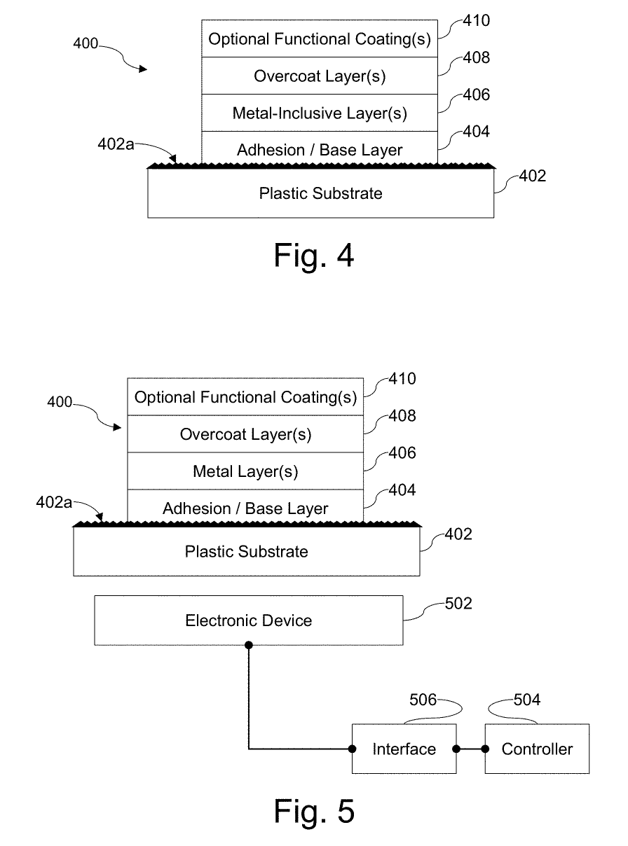

FIG. 4 is a cross-sectional view of a trim component 400 supporting a coating in accordance with certain example embodiments. The trim component 400 includes a plastic substrate 402, including at least one surface to be coated. For reasons explained in greater detail below, the surface to be coated 402a is textured so as to have a desired roughness. Texturing may be accomplished using an acid or other etchant, sandblasting, plasma ablation, scanning a laser or other energy source over the substrate 402, coating the samples at an angle, forming coatings at a high pressure, using a textured stamp or other means to emboss or otherwise form a micro-textured pattern, using a mesh or other screen during coating, and/or via any other suitable technique.

Once textured, an optional adhesion/base layer 404 is formed on the plastic substrate 402. The adhesion/base layer 404 may include Si, Ni, Cr, Ti, and/or the like. Oxides of these materials also may be used. Thus, the adhesion/base layer 404 certain example embodiments comprises silicon oxide, chromium oxide, nickel chrome, nickel chrome oxide, and/or the like. In certain example embodiments, the layers may be stoichiometric. In certain other example embodiments, it may be advantageous to use sub-oxided layers (e.g., a layer comprising SiOx, where 1<x<2). Sub-oxide materials form strong bonds with carbon in the plastic substrate 402. In certain example embodiments, the adhesion/base layer 404 may be 5-100 nm thick, more preferably 10-50 nm thick, and still more preferably 10-30 nm thick.

One or more metal-inclusive layers 406 are formed on the adhesion/base layer 404. The one or more metal-inclusive layers 406 may include layer(s) comprising NiCr, Cr, Ti, TiCr, TiOx, TiONx, Al, Zr, ZrTi, and/or the like. A layer comprising NiCr turned out to have a bright reflection but had a reddish tint in transmission. It has been found that a single layer comprising Cr provides a good color match compared to conventional electroplated samples. In this regard, the layer comprising Cr had less reflection compared to the layer comprising NiCr, but was a neutral absorber and did not show any apparent changes in transmission color. When NiCr and Cr were both coated together and formed a layer (with 50% of the material coming from the former, and 50% of the material coming from the latter), the appearance averaged out and brought the reflection higher without having a large absorption. Thus, certain example embodiments may advantageously incorporate a layer formed from NiCr and Cr targets. It thus will be appreciated that a metal-inclusive layer in the stack can be used to assist in the desired coloration for the trim component 400. Furthermore, a layer comprising TiOx and/or TiONx may be desirable in certain example embodiments, because they can be optically tuned to provide for variable color match opportunities.

The thickness of the metal-inclusive layer(s) 406 may be selected based on, for example, the material(s) used for the adhesion/base layer 404, the overcoat layer(s) 408 formed on the metal-inclusive layer(s) 406, the material(s) selected for the metal-inclusive layer(s) 406, and the desired transmission through trim component 400. A transmission of 5-30%, more preferably 10-30%, through trim component 400 generally is desirable for a wide range of applications, and a layer comprising chromium that is 10-21.5 nm thick may be suitable in this environment. As another example, a thickness of about 17 nm for a layer comprising chromium may be used to achieve 15% optical transmission through the trim component 400. It has been determined, however, that a transmission of 1% through trim component 400 may be suitable for some applications, e.g., as a 1% optical transmission value has been determined to be effective for at least some backlight applications. Thus, certain example embodiments may target a transmission range of 1-15%.

The overcoat layer(s) 408 provides mechanical and/or chemical protection for the underlying metal-inclusive layer(s) 406. A low coefficient of friction material may be used with respect to the former. Chemical durability provided by the overcoat layer(s) 408 advantageously slows or otherwise halts corrosion of the underlying metal-inclusive layer(s) 406, which otherwise likely would change the coloration of the coating. The overcoat layer(s) 408 may include layer(s) comprising zirconium oxide, silicon oxide, silicon nitride, silicon oxynitride, and/or the like. Silicon-inclusive layers (including silicon nitride inclusive layers) may be advantageous in terms of providing mechanical and chemical durability, while also serving as good bases on which optional additional functional coating(s) 410 can be formed. Silicon-inclusive layers (including silicon nitride inclusive layers) in this sense provide a good optical break, while also promoting good adhesion between the optional additional functional coating(s) 410 and the underlying layer(s). The overcoat layer(s) 408 in certain example embodiments may be 1-300 nm thick, more preferably 1-100 nm thick, still more preferably 3-50 nm thick, and more preferably still 3-10 nm thick.

One or more functional coating(s) 410 optionally may be provided as outermost layers for the trim component 400. Anti-fog, self-cleaning, anti-smudge, hydrophobic, and/or other coatings may be used in this regard. In general, photocatalytically-activated materials such as, for example, anatase TiO₂, may be used to provide self-cleaning features. Hydrophobic coatings (e.g., coatings with contact angles greater than about 90 degrees) also may be used for self-cleaning, anti-fog, and/or other purposes. Anti-scratch, anti-corrosion, anti-fingerprint, electrically conducting, dynamic transmission/reflection/absorption, etc., coatings additionally or alternatively may be provided in certain example embodiments. Self-cleaning coatings may, for example, implement a layer comprising anatase TiO₂ that is about 10-20 nm thick. An anti-scratch coating may, for example, implement a layer comprising DLC that is about 1-5 nm thick.

It will be appreciated that PVD techniques may be used to form some or all of the layers described in connection with the FIG. 4 example. Sputtering may be used in this regard. Advantageously, low-temperature or room-temperature sputtering may be advantageous in terms of allowing a wide range of materials (including plastics) to be used for the substrate 402.

When formed (e.g., molded), the surface to be coated 402a the plastic substrate 402 has an initial roughness. As alluded to above, this surface 402a is textured to a desired roughness in certain example embodiments. The need to texture in this manner was determined as a result of samples produced to include the FIG. 4 layer stack but absent the textured samples. More particularly, three sets with five samples each were produced to attempt to mimic the matte finish of the sample shown in and described in connection with FIGS. 1a-3e and the table above. Each of these sets of samples was determined to lack a desirable matte aesthetic and thus insufficiently match the electroplated baseline. The following table includes average roughness values for each of the three sample sets.

| | Ra | | Rz | | RSm | |
|---|---|---|---|---|---|---|
| | Avg. | Std. Dev. | Avg. | Std. Dev. | Avg. | Std. Dev. |
| | (um) | (um) | (um) | (um) | (um) | (um) |
| Set 1 | 1.098 | 0.256 | 6.385 | 1.353 | 95.949 | 38.243 |
| Set 2 | 1.094 | 0.283 | 6.427 | 1.445 | 102.252 | 43.291 |
| Set 3 | 0.912 | 0.230 | 6.290 | 1.686 | 77.878 | 33.692 |

Insufficient matches were realized as noted above, despite common substrate materials being used. It is believed that the discrepancy is attributable in large part to differences resulting from the formation techniques used. More particularly, electroplating (at least when performed on molded plastic surfaces) leveled imperfections in the plastic substrate, resulting in a smooth coating with a desirable appearance. The chrome formed on the plastic was non-conformal, yet not so smoothing/leveling that a bright appearance was achieved for these samples. There is thus a careful balance in the amount of smoothing/leveling achieved via electroplating suitable for matte vs. bright finishes.

On the other hand, sputtering tends to yield layers that are conformal with respect to their underlying surfaces. The sputtered coatings produced in this set of samples were indeed found to be conformal with respect to the underlying plastic substrate surface. It is believed that the lack of the leveling effect contributed to the heightened roughness and undesirable aesthetic appearance. To help resolve the issue created by the generally non-leveling and generally conformal nature of the sputtered coatings relative to the surfaces of the substrates to be coated, as noted above, certain example embodiments texture and/or otherwise condition such surfaces. Again, care is taken to ensure that the roughness characteristics match the desired chrome aesthetic for matte and bright finishes.

The following characteristics may be desirable for use in connection with certain matte-finish embodiments:

L*=80 to 85 (more preferably 80 to 82.5, e.g., 81.50)

a*=0 to −1.5 (more preferably −0.79 to −0.85, e.g., −0.82)

b*=0 to -1.5 (more preferably 0 to −0.4, e.g., −0.17)

Gloss=100 to 135 (more preferably 108 to 132, e.g., 119.7)

It is noted that these values may be used for the entire trim component, not just the metal-inclusive layer only.

New features have been added into automotive interior and exterior designs, such as backlighting, LIDAR sensors, radar/RADOME sensors, touch sensors, etc. These features may be useful for providing accent lighting, active cruise control, collision detection, etc. These features sometimes require optical and/or other transmission through trim components, which conventionally have been opaque. Certain example embodiments provide trim components that in some ways may be thought of as being “two-way” dielectric mirrors.

In this regard, FIG. 5 is a schematic view of a trim component 400 with an associated electronic device 502, in accordance with certain example embodiments. The trim component 400 is like the FIG. 4 example, but there is an electronic device 502 provided “behind” it (i.e., on a second surface of the plastic substrate 402). The electronic device 502 is electrically coupled to a controller via an interface 506. As will be appreciated by those skilled in the art, the interface 506 may be a USB interface, LIN bus, and/or the like. The controller 506 may include any suitable combination of hardware, software, firmware, and/or the like. For example, at least one hardware processor may be coupled to a memory storing instructions that, when executed, control the electronic device 502 via the interface 506 to perform desired functionality.

Depending on the application in which the FIG. 5 example is used, the electronic device 502 may include LED and/or other lights (e.g., for decorative backlighting, to “light up” interfaces used for keyless entry or other purposes), touch sensors, laser and/or radar related rangefinders, etc.

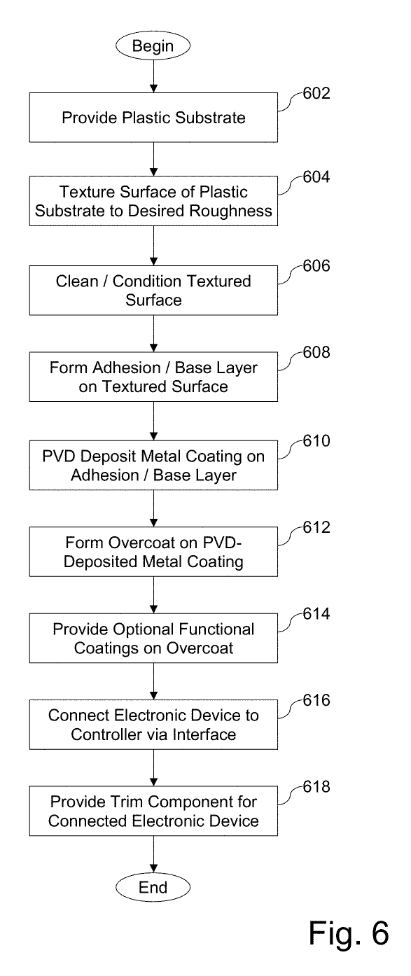

FIG. 6 is a flowchart showing a method of making the FIG. 5 example trim component, in accordance with certain example embodiments. A plastic substrate is provided in step 602. The surface of the plastic substrate is textured to a desired roughness in step 604. In step 606, the textured surface is cleaned and/or conditioned. Good surface activation and/or cleaning of the surface to be coated is advantageous, as outgassing, etc., from the plastic otherwise could damage the coating as the layers are being formed, thereby threatening the longevity of the coating. For example, outgassing of material from the plastic tends to damage interfaces, increasing the likelihood that the coating could crack, peel off, etc.

In step 608, the adhesion/base layer is formed on the cleaned and/or conditioned textured surface. The metal-inclusive coating is PVD deposited or otherwise formed on the adhesion/base layer, in step 610. In step 612, the overcoat is formed on the metal-inclusive coating. One or more optional functional coatings are provided on the overcoat in step 614.

With respect to electronic components to be positioned relative to the trim component, if any, the electronic device is connected to the controller via the interface in 616. The trim component and the electronic device are oriented relative to one another in step 618. For example, the trim component likely will be placed over the electronic device in a vehicle, e.g., for lighting, touch panel, LIDAR, radar/RADOME, and/or other purposes.

The example techniques described herein are advantageous for a number of reasons. For example, by forming features on the plastic substrate surface, it is possible in certain example embodiments to reduce the need for (and sometimes completely eliminate) a top wet haze coating and provide for a “cold” metallic surface that feels more true (e.g., in that it more closely matches conventional electroplated chrome). As another example, by forming features on the plastic substrate surface, a large surface area is created, thereby enabling the production of satin chrome looking components without the absolute need for a base adhesion layer (e.g., formed via a wet or other process). As still another example, using PVD sputtering technology enables more precise control over optical spectral transmission (and reflection), color matching, etc., so that desired appearances can be achieved for satin and glossy components. Certain example embodiments also are advantageously in that PVD sputtering technology facilitates the addition of functional features to the chrome-looking surface including, for example, features for anti-scratch, anti-corrosion, anti-fingerprint, electrically conducting, dynamic transmission/reflection/absorption, etc., performance.

As will be appreciated from the description above, the trim components of certain example embodiments may be used for interior and/or exterior vehicle or other applications, e.g., in connection with functional and/or decorative elements.

Although certain example embodiments have been described as including an adhesion promoting bonding layer closest to the plastic substrate and/or a protective uppermost layer or layers, certain other example embodiments may omit one or both. That is, in certain example instances, sufficient adhesion promotion can be achieved via surface texturing and/or surface treatment. These techniques may involve, for example, roughing the surface to increase the effective surface area to which the color-providing layer (for example) can adhere. This may be performed using a plasma treatment (in the atmosphere or in vacuum), via an ion beam, and/or the like. In certain example embodiments, the roughness of the substrate will be increased and a first stratum of the color-providing layer (for example) can adhere well to it. That stratum, or another stratum formed thereon, may be formed to have a roughness profile and/or other physical characteristics to impart the desired optical characteristics (including transmission and coloration). This may involve, for instance, a first stratum at least partially leveling the roughened surface, and a second stratum serving a more completely leveling function. Thus, the roughness of the substrate and the roughness of the color-providing coating may or may not match in different example embodiments. In certain example embodiments, adhesion may be promoted via other surface treatments that, for example, realign molecules of the plastic substrate, provide additional bonding sites, create areas promoting strong adatom attachment and crystalline growth, etc. In these and/or other embodiments, the protective uppermost layer may be omitted. For example, by providing a sufficiently smooth metal-inclusive layer, the coefficient of friction may be sufficiently low as to reduce the likelihood of damage to the coating upon exposure to the environment. Additionally, or alternatively, the material selected as the color-providing layer may be sufficiently robust as to provide for enhanced mechanical and/or chemical durability. Still further, additionally or alternatively, certain example embodiments may be made more mechanically robust by virtue of being engineered to have a desirable stress regime (e.g., net compressive in some instances), which may be facilitated by virtue of the roughened substrate surface, etc. In general, in at least some instances, bonding strength will increase with surface area increases provided by texturing, surface treatment, and/or the like, thereby resulting in adhesion promotion and/or robustness of the coating. In certain example embodiments, the trim components may be provided in locations that are not subject to environmental exposure and, thus, the need for high adhesion and durability may be relaxed.

Although certain example embodiments have been described as including color-providing layers that are metal inclusive (and, for instance, include chromium), it will be appreciated that different materials may be used to achieve a desired chrome coloration. For example, semi-conductive materials such as Ge and Si, and dielectric materials such as TiNx for example may be used to achieve desired coloration and transmission properties. It has been found that, from a design perspective, final transmission through the component may be set, and that the thickness(es) of the layer(s) used to obtain the desired coloration may be derived thereafter. Roughness of the substrate also may be used to achieve warmer or cooler coatings, once transmission has been set. Although certain example embodiments implement a single layer for providing a desired coloration, different example embodiments may implement multiple different layers in a layer stack for this purpose.

In a somewhat related regard, although certain example embodiments have been described as involving a chrome or chrome-like appearance, it will be appreciated that it may be desirable in some instances to provide different aesthetic properties. For instance, in some instances, it may be desirable to provide a gold, rose-gold, or other coloration for a trim component. Materials may be selected to achieve the desired coloration and, in this regard, may include, for example, gold, gold alloys, TiONx, and/or the like.

As used herein, the terms “on,” “supported by,” and the like should not be interpreted to mean that two elements are directly adjacent to one another unless explicitly stated. In other words, a first layer may be said to be “on” or “supported by” a second layer, even if there are one or more layers therebetween.

In certain example embodiments, a method of making a trim component for a vehicle is provided. The trim component includes a plastic substrate, and the plastic substrate includes a surface to be coated that is formed to have a first desired roughness profile. A color-providing layer is physical vapor deposition deposited, directly or indirectly, on the surface to be coated, with the color-providing layer being formed to have a roughness, coloration, and gloss, sufficient to impart a desired warm or cool aesthetic appearance for the trim component.

In addition to the features of the previous paragraph, in certain example embodiments, the surface to be coated may be cleaned prior to the deposition of the color-providing layer.

In addition to the features of either of the two previous paragraphs, in certain example embodiments, the surface to be coated may be treated, e.g., to reduce the incidence of outgassing during the deposition of the color-providing layer, compared to a situation in which there is no such treating.

In addition to the features of any of the three previous paragraphs, in certain example embodiments, the first desired roughness profile may be created via a plasma treatment.

In addition to the features of any of the four previous paragraphs, in certain example embodiments, the first desired roughness profile may be created via an ion beam.

In addition to the features of any of the five previous paragraphs, in certain example embodiments, the color-providing layer may include a metal. For instance, in certain example embodiments, the color-providing layer may include Cr, e.g., so that the trim component is made to have a chrome-like aesthetic appearance. Alternatively, for instance, in certain example embodiments, the color-providing layer may include Au, e.g., so that the trim component is made to have a gold-like or rose gold like aesthetic appearance.

In addition to the features of any of the six previous paragraphs, in certain example embodiments, the color-providing layer may include titanium oxide or titanium oxynitride.

In addition to the features of any of the seven previous paragraphs, in certain example embodiments, the color-providing layer may comprise a transition element selected to contribute to the desired aesthetic appearance of the trim component.

In addition to the features of any of the eight previous paragraphs, in certain example embodiments, the color-providing layer may be dielectric and may include one or more materials selected to contribute to the desired aesthetic appearance of the trim component.

In addition to the features of any of the nine previous paragraphs, in certain example embodiments, the trim component may lack an adhesive-promoting base layer between the color-providing layer and the surface to be coated.

In addition to the features of any of the 10 previous paragraphs, in certain example embodiments, the color-providing layer may be provided in direct physical contact with the surface to be coated.

In addition to the features of any of the 11 previous paragraphs, in certain example embodiments, the color-providing layer may include first and second major surfaces, with the first surface being closer to the substrate than the second surface, and the color-providing layer may be formed to have a second desired roughness profile for the second surface thereof.

In addition to the features of the previous paragraph, in certain example embodiments, the first and second desired roughness profiles may be different from one another.

In addition to the features of either of the two previous paragraphs, in certain example embodiments, a first stratum of the color-providing layer may be deposited so as to level the surface to be coated.

In addition to the features of the previous paragraph, in certain example embodiments, a second stratum of the color-providing layer may be provided over the first stratum and may be deposited so as to impart the second desired roughness profile to the color-providing layer.

In certain example embodiments, a method of making a vehicle is provided. A trim component is made in accordance with the method of any one of the 15 previous paragraphs, in certain example embodiments. An electronic component is provided. The electronic component is connected to a controller via an electronic interface. The trim component is oriented in the vehicle in a desired spatial relation relative to the electronic component.

In addition to the features of the previous paragraph, in certain example embodiments, the electronic component may comprise backlights.

In addition to the features of either of the two previous paragraphs, in certain example embodiments, the electronic component may comprise a laser and/or radar source.

In certain example embodiments, a metallic-looking trim component for a vehicle is provided. A physical vapor deposition (PVD) deposited color-providing layer is formed, directly or indirectly, on the surface, with the color-providing layer being formed to have a roughness, coloration, and gloss, sufficient to impart a desired warm or cool aesthetic appearance for the metallic-looking trim component.

In addition to the features of the previous paragraph, in certain example embodiments, the color-providing layer may be provided in direct physical contact with the surface.

In addition to the features of either of the two previous paragraphs, in certain example embodiments, the color-providing layer may include first and second major surfaces, the first surface being closer to the substrate than the second surface; the color-providing layer may be formed to have a second desired roughness profile for the second surface thereof; and the first and second desired roughness profiles may be different from one another.

In certain example embodiments, a vehicle comprising the trim component of any of the three previous paragraphs is provided.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. A method of making a trim component for a vehicle, the trim component including a plastic substrate, the method comprising:
having the plastic substrate, the plastic substrate including a surface to be coated that is formed to have a first desired roughness profile;
physical vapor deposition depositing a color-providing layer, directly or indirectly, on the surface to be coated, the color-providing layer being formed to have a roughness, coloration, and gloss, sufficient to impart a desired warm or cool aesthetic appearance for the trim component.

2. The method of claim 1, further comprising cleaning the surface to be coated prior to the deposition of the color-providing layer.

3. The method of claim 1, further comprising treating the surface to be coated to reduce the incidence of outgassing during the deposition of the color-providing layer, compared to a situation in which there is no such treating.

4. The method of claim 1, wherein the first desired roughness profile is created via a plasma treatment.

5. The method of claim 1, wherein the first desired roughness profile is created via an ion beam.

6. The method of claim 1, wherein the color-providing layer includes a metal.

7. The method of claim 6, wherein the color-providing layer includes Cr so that the trim component is made to have a chrome-like aesthetic appearance.

8. The method of claim 6, wherein the color-providing layer includes Au so that the trim component is made to have a gold-like or rose gold like aesthetic appearance.

9. The method of claim 1, wherein the color-providing layer includes titanium oxide.

10. The method of claim 1, wherein the color-providing layer includes titanium oxynitride.

11. The method of claim 1, wherein the color-providing layer comprises a transition element selected to contribute to the desired aesthetic appearance of the trim component.

12. The method of claim 1, wherein the color-providing layer is dielectric and includes one or more materials selected to contribute to the desired aesthetic appearance of the trim component.

13. The method of claim 1, wherein the trim component lacks an adhesive-promoting base layer between the color-providing layer and the surface to be coated.

14. The method of claim 1, wherein the color-providing layer is provided in direct physical contact with the surface to be coated.

15. The method of claim 1, wherein the color-providing layer includes first and second major surfaces, the first surface being closer to the substrate than the second surface, and wherein the color-providing layer is formed to have a second desired roughness profile for the second surface thereof.

16. The method of claim 15, wherein the first and second desired roughness profiles are different from one another.

17. The method of claim 15, wherein a first stratum of the color-providing layer is deposited so as to level the surface to be coated.

18. The method of claim 17, wherein a second stratum of the color-providing layer is provided over the first stratum and is deposited so as to impart the second desired roughness profile to the color-providing layer.

19. A method of making a vehicle, the method comprising:
having a trim component made in accordance with the method of claim 1;
providing an electronic component;
connecting the electronic component to a controller via an electronic interface; and
orienting the trim component in the vehicle in a desired spatial relation relative to the electronic component.

20. The method of claim 19, wherein the electronic component comprises backlights.

21. The method of claim 29, wherein the electronic component comprises a laser and/or radar source.

22. A metallic-looking trim component for a vehicle, comprising:
a plastic substrate including a surface supporting a coating, the surface being formed to have a first desired roughness profile;
a physical vapor deposition (PVD) deposited color-providing layer formed, directly or indirectly, on the surface, the color-providing layer being formed to have a roughness, coloration, and gloss, sufficient to impart a desired warm or cool aesthetic appearance for the metallic-looking trim component.

23. The trim component of claim 22, wherein the color-providing layer is provided in direct physical contact with the surface.

24. The trim component of claim 22, wherein the color-providing layer includes first and second major surfaces, the first surface being closer to the substrate than the second surface;
wherein the color-providing layer is formed to have a second desired roughness profile for the second surface thereof; and
wherein the first and second desired roughness profiles are different from one another.

25. A vehicle comprising the trim component of claim 22.
